(19) United States
(12) Patent Application Publication
(10) Pub. No.: US 2008/0217519 A1
(43) Pub. Date: Sep. 11, 2008

(54) Photoelectric conversion device

(76) Inventors: Masahiro Yokomichi, Chiba-shi (JP); Daisuke Muraoka, Chiba-shi (JP); Daisuke Okano, Chiba-shi (JP); Satoshi Machida, Chiba-shi (JP)

Correspondence Address: BRUCE L. ADAMS, ESQ.;ADAMS & WILKS, SUITE 1231, 17 BATTERY PLACE, NEW YORK, NY, 10004, US

(21) Appl. No.: 12/070,964

(22) Filed: Feb. 22, 2008

(30) Foreign Application Priority Data
Feb. 27, 2007 (JP) 2007-047142

(51) Int. Cl. H03F 3/08

(52) U.S. Cl. 250/214 A

(57) ABSTRACT

Provide is a photoelectric conversion device capable of correcting an optical signal with high accuracy and more adaptable to high-speed operations, including: an optical signal common output line (10) commonly connected to all the photoelectric conversion units (30), for outputting an amplified optical signal from each of the photoelectric conversion units in chronological order, and having a first parasitic capacitor (31); an initial voltage common output line (11) commonly connected to all the photoelectric conversion units (30), for outputting the amplified initial voltage from each of the photoelectric conversion units (30) in chronological order, and having a second parasitic capacitor (32); and a capacitor group (20) commonly connected to one of the optical signal common output line (10) and the initial voltage common output line (11), which has a capacitance value substantially equal to a differential capacitance value between the first parasitic capacitor (31) and the second parasitic capacitor (32).

### BACKGROUND OF THE INVENTION

1. Field of the Invention

The present invention relates to a photoelectric conversion device for outputting an output voltage according to incident light.

2. Description of the Related Art

At present, there is employed a photoelectric conversion device for an image reader such as a facsimile machine, an image scanner, a digital copier, and an X-ray image pick-up device. The photoelectric conversion device is produced using a single crystal silicon chip, and a contact image sensor (CIS) is well known as an example thereof.

In this case, a photoelectric conversion device according to a related art will be described.

The photoelectric conversion device includes a plurality of photodiodes, noise signal holding means that reads a noise signal from each of the photodiodes and holds the read noise signal, and optical signal holding means that reads an optical signal from each of the photodiodes and holds the read optical signal. The photoelectric conversion device further includes a noise signal common output line connected to each of the photodiodes, for outputting the noise signal, and an optical signal common output line connected to each of the photodiodes, for outputting the optical signal. The photoelectric conversion device further includes reading means that reads the noise signal held by the noise signal holding means and the optical signal held by the optical signal holding means through capacitance division between a capacitance associated with the noise signal common output line and a capacitance associated with the optical signal common output line. The photoelectric conversion device further includes a switch that is provided between the noise signal common output line and the optical signal common output line, and is turned on so as to eliminate an imbalance between a voltage at the noise signal common output line and a voltage at the optical signal common output line, to thereby correct the optical signal with high accuracy (for example, see JP 10-191173 A).

In the above-mentioned configuration, with the achievement of a higher degree of integration of a single crystal silicon chip and achievement of a higher density of each of an element and metal wiring, even when the noise signal common output line and the optical signal common output line are out of balance in terms of a mask layout design, an imbalance in voltage between the noise signal common output line and the optical signal common output line can be eliminated and the optical signal can be corrected with high accuracy.

However, the switch provided between the noise signal common output line and the optical signal common output line, for correcting the optical signal with high accuracy, is turned on and then turned off. After that, the noise signal and the optical signal are read by the noise signal common output line and the optical signal common output line, respectively. As a result, a time for reading the noise signal and the optical signal is reduced by an amount of time required for the switch to operate. Therefore, it is difficult for the photoelectric conversion device to achieve high-speed operations.

### SUMMARY OF THE INVENTION

The present invention has been made in view of the above-mentioned circumstances, and therefore, it is an object of the present invention is to provide a photoelectric conversion device capable of correcting an optical signal with high accuracy and more adaptable to high-speed operations.

In order to solve the above-mentioned problems, according to the present invention, there is provided a photoelectric conversion device for outputting an output voltage according to incident light, including:

a plurality of photoelectric conversion units each including:
optical signal output means which outputs an optical signal according to the incident light;
reset means which is connected to an output terminal of the optical signal output means and which resets a voltage at the output terminal of the optical signal output means to a predetermined initial voltage;
amplification means which is connected to the output terminal of the optical signal output means and which amplifies the optical signal to output the amplified optical signal and amplifies the initial voltage to output the amplified initial voltage;
optical signal holding means which is connected to an output terminal of the amplification means and which holds the amplified optical signal; and
initial voltage holding means which is connected to the output terminal of the amplification means and which holds the amplified initial voltage;

an optical signal common output line commonly connected to all the plurality of photoelectric conversion units, for outputting the amplified optical signal from each of the plurality of photoelectric conversion units in chronological order, and having a first parasitic capacitance;

an initial voltage common output line commonly connected to all the plurality of photoelectric conversion units, for outputting the amplified initial voltage from each of the plurality of photoelectric conversion units in chronological order, and having a second parasitic capacitance;

an adjustment capacitor commonly connected to one of the optical signal common output line and the initial voltage common output line, which has a capacitance value substantially equal to a differential capacitance value between the first parasitic capacitance and the second parasitic capacitance; and

a subtraction amplifier for subtracting the amplified initial voltage from the amplified optical signal.

In the present invention, the adjustment capacitor having the capacitance value substantially equal to the differential capacitance value between the first parasitic capacitance associated with the optical signal common output line and the second parasitic capacitance associated with the initial voltage common output line is connected to the optical signal common output line or to the initial voltage common output line. Accordingly, the parasitic capacitance associated with the optical signal common output line and the parasitic capacitance associated with the initial voltage common output line are equal to each other. As a result, an effect of the parasitic capacitance on the optical signal is eliminated, and the optical signal is corrected with high accuracy.

Further, the adjustment capacitor is connected to the optical signal common output line or to the initial voltage common output line. In addition, the adjustment capacitor is not controlled by the signal, and thus, a time for controlling the adjustment capacitor is unnecessary. Accordingly, a time for reading the optical signal and the initial voltage is not reduced. As a result, the photoelectric conversion device is more adaptable to high-speed operations.

### BRIEF DESCRIPTION OF THE DRAWINGS

In the accompanying drawings:

FIG. 1 is a circuit diagram showing a photoelectric conversion device;

FIG. 2 is a circuit diagram showing a pre-stage portion of the photoelectric conversion device;

FIG. 3 is a circuit diagram showing a post-stage portion of the photoelectric conversion device;

FIG. 4 is a diagram showing a first capacitor group; and

FIG. 5 is a diagram showing a second capacitor group.

### DETAILED DESCRIPTION OF THE PREFERRED EMBODIMENTS

Hereinafter, an embodiment of the present invention will be described in detail with reference to the accompanying drawings.

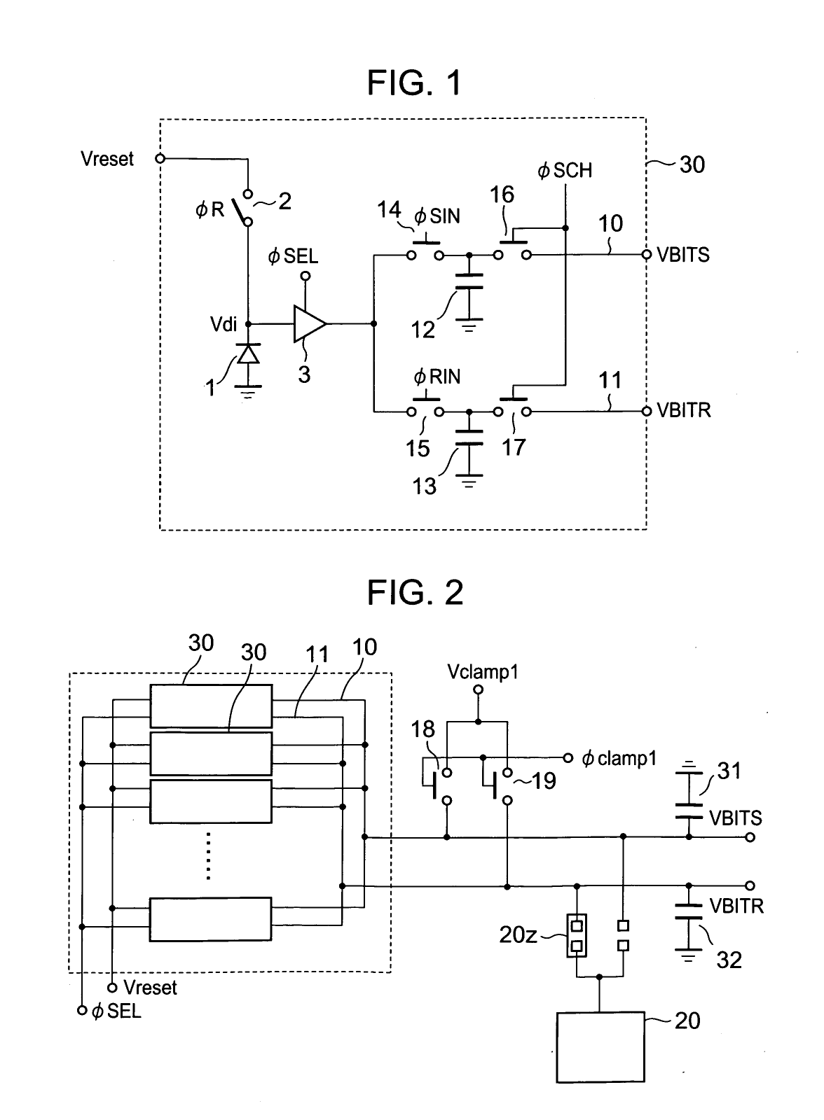

First, a description is given of a configuration of a photoelectric conversion unit mounted to a photoelectric conversion device for outputting an output voltage according to incident light. FIG. 1 is a circuit diagram showing the photoelectric conversion unit.

A photoelectric conversion unit 30 includes a photodiode 1, a reset switch 2, a buffer amplifier 3, a switch 14, a switch 15, a capacitor 12, a capacitor 13, a switch 16, and a switch 17.

The reset switch 2 and the buffer amplifier 3 are each connected to an output terminal of the photodiode 1. The capacitor 12 is connected to an output terminal of the buffer amplifier 3 through the switch 14, and the capacitor 13 is connected to the output terminal of the buffer amplifier 3 through the switch 15. Moreover, the capacitor 12 is connected to an optical signal common output line 10 through the switch 16, and the capacitor 13 is connected to an initial voltage common output line 11 through the switch 17.

The photodiode 1 generates photoelectric charges according to incident light and outputs an optical signal according to the photoelectric charges. The reset switch 2 resets a voltage at the output terminal of the photodiode 1 to a predetermined initial voltage. The buffer amplifier 3 amplifies the optical signal to output an amplified optical signal, and amplifies the initial voltage to output an amplified initial voltage. The capacitor 12 holds the amplified optical signal, and the capacitor 13 holds the amplified initial voltage.

Next, a description is given of a configuration of a pre-stage portion of the photoelectric conversion device. FIG. 2 is a circuit diagram showing the pre-stage portion of the photoelectric conversion device.

The pre-stage portion of the photoelectric conversion device includes a plurality of photoelectric conversion units 30, the optical signal common output line 10, the initial voltage common output line 11, a switch 18, a switch 19, a capacitor group 20, a metal wiring 20z, a first parasitic capacitor 31, and a second parasitic capacitor 32.

The optical signal common output line 10 is commonly connected to all the photoelectric conversion units 30 and has the first parasitic capacitor 31. The initial voltage common output line 11 is commonly connected to all the photoelectric conversion units 30 and has the second parasitic capacitor 32. The optical signal common output line 10 is applied with a voltage Vclamp1 through the switch 18. The initial voltage common output line 11 is applied with the voltage Vclamp1 through the switch 19. The capacitor group 20 is connected to the optical signal common output line 10 or to the initial voltage common output line 11.

The optical signal common output line 10 outputs the amplified optical signals from each of the photoelectric conversion units 30 in chronological order. The initial voltage common output line 11 outputs the amplified initial voltages from each of the photoelectric conversion units 30 in chronological order. The capacitor group 20 has a capacitance value substantially equal to a differential capacitance value between the first parasitic capacitor 31 and the second parasitic capacitor 32.

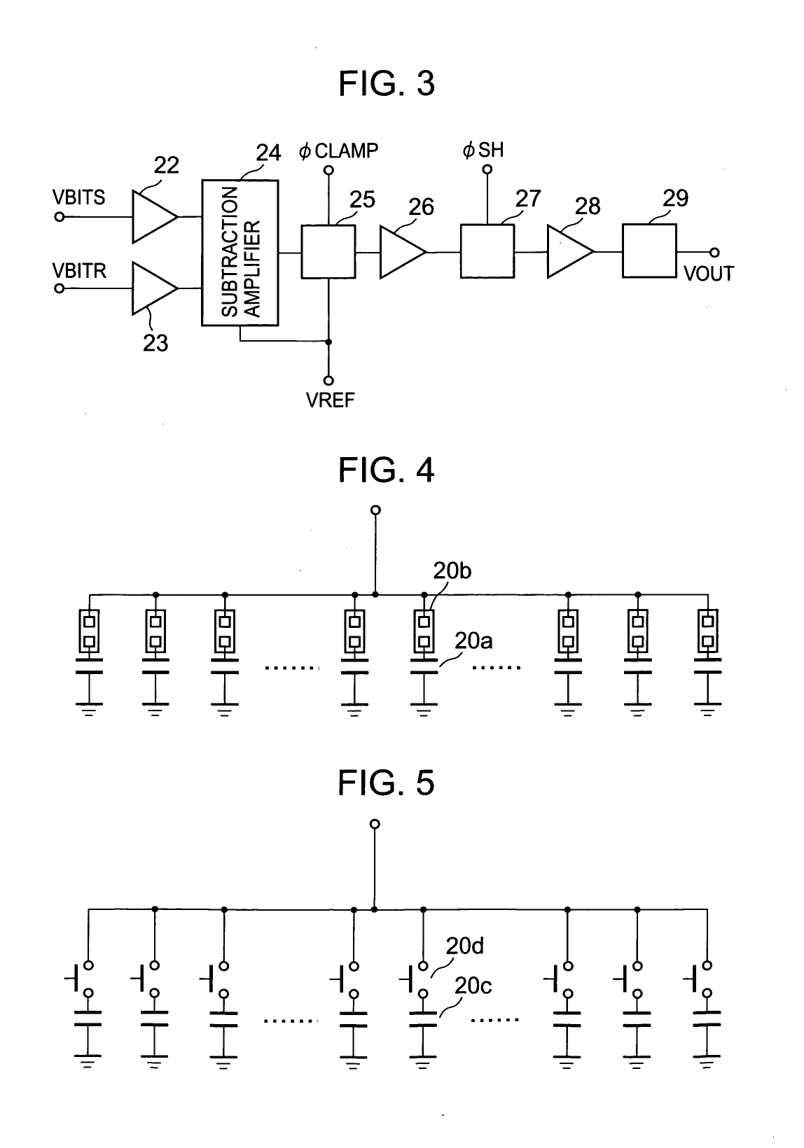

Next, a description is given of a configuration of a post-stage portion of the photoelectric conversion device. FIG. 3 is a circuit diagram showing the post-stage portion of the photoelectric conversion device.

The post-stage portion of the photoelectric conversion device includes a buffer amplifier 22, a buffer amplifier 23, a subtraction amplifier 24, a clamp circuit 25, a buffer amplifier 26, a sample hold circuit 27, a buffer amplifier 28, and a transmission gate 29.

The optical signal common output line 10 is connected to the subtraction amplifier 24 through the buffer amplifier 22, and the initial voltage common output line 11 is connected to the subtraction amplifier 24 through the buffer amplifier 23. An output terminal of the subtraction amplifier 24 is connected to the clamp circuit 25, and an output terminal of the clamp circuit 25 is connected to the buffer amplifier 26. An output terminal of the buffer amplifier 26 is connected to the sample hold circuit 27, and an output terminal of the sample hold circuit 27 is connected to the buffer amplifier 28. An output terminal of the buffer amplifier 28 is connected to the transmission gate 29.

Next, a description is given of operations of the photoelectric conversion unit 30.

When the reset switch 2 is turned on in response to a signal ØR, a voltage Vdi at the output terminal of the photodiode 1 is set to a reset voltage Vreset. After that, when the switch 2 is turned off in response to the signal ØR, the voltage Vdi is set to a voltage (hereinafter, referred to as “initial voltage”) which is obtained by adding a noise voltage Voff associated with the photodiode 1 to the reset voltage Vreset. Immediately after the reset switch 2 is turned off, the switch 15 is turned on in response to a signal GRIN, and the initial voltage is set to an amplified initial voltage VBITR through the buffer amplifier 3 controlled in response to a signal ØSEL, whereby the amplified initial voltage VBITR is read by the capacitor 13. The amplified initial voltage VBITR is read from a time when the reset switch 2 is turned off until the switch 15 is turned off.

After that, the photodiode 1 generates photoelectric charges according to incident light and holds the generated photoelectric charges, and the voltage Vdi fluctuates according to an amount of the photoelectric charges. Then, the voltage Vdi is set to a voltage (hereinafter, referred to as “optical signal”) which is obtained by adding, to the reset voltage Vreset, the noise voltage Voff associated with the photodiode 1 and the voltage according to the amount of photoelectric charges held by the photodiode 1. The switch 14 is turned on in response to a signal ØSIN, and the optical signal becomes an amplified optical signal VBITS through the buffer amplifier 3, whereby the amplified optical signal is read by the capacitor 12. The amplified optical signal VBITS is read from the time when the reset switch 2 is turned off until the switch 14 is turned off.

The switch 16 and the switch 17 are simultaneously turned on in response to a signal ØSCH. In addition, when predetermined conditions are satisfied, the amplified optical signal VBITS and the initial voltage VBITR are read by the optical signal common output line 10 and the initial voltage common output line 11, respectively. The post-stage circuit subtracts the initial voltage VBITR from the amplified optical signal VBITS, thereby taking out an output voltage according to the amount of the photoelectric charges corresponding to the incident light.

The operation of reading the amplified initial voltage VBITR by the capacitor 13 and the operation of reading the amplified optical signal VBITS by the capacitor 12 are repeatedly performed.

Next, a description is given of operations of the pre-stage portion of the photoelectric conversion device.

In this case, each of the photoelectric conversion units 30 outputs the amplified optical signal VBITS and the amplified initial voltage VBITR in chronological order.

When the signal ØSCH becomes high and a signal Øclamp1 becomes low (hereinafter, referred to as “first half period”), the switch 16 and the switch 17 are turned on, and the switch 18 and the switch 19 are turned off. Accordingly, the amplified optical signal VBITS from the predetermined photoelectric conversion unit 30, which is held in the capacitor 12, is read to the optical signal common output line 10 according to a voltage division ratio between the capacitor 12 and the first parasitic capacitor 31. Simultaneously, the amplified initial voltage VBITR from the predetermined photoelectric conversion unit 30, which is held in the capacitor 13, is read by the initial voltage common output line 11 according to a voltage division ratio between the capacitor 13 and the second parasitic capacitor 32.

When the signal ØSCH becomes high and the signal Øclamp1 also becomes high (hereinafter, referred to as “second half period”), the switch 16 and the switch 17 are turned on, and the switch 18 and the switch 19 are also turned on. Accordingly, the voltages at the optical signal common output line 10 and the initial voltage common output line 11 are each initialized to the voltage Vclamp1.

The optical signal common output line 10 has the first parasitic capacitor 31 and is affected by the first parasitic capacitor 31. The initial voltage common output line 11 has the second parasitic capacitor 32 and is affected by the second parasitic capacitor 32. The optical signal common output line 10 or the initial voltage common output line 11 has the capacitor group 20 having the capacitance value substantially equal to the differential capacitance value between the first parasitic capacitor 31 and the second parasitic capacitor 32, and is affected by the capacitor group 20. Accordingly, the effect of the capacitor on the optical signal common output line 10 is equivalent to the effect of the capacitor on the initial voltage common output line 11.

In this case, for example, the buffer amplifier 3, the buffer amplifier 22, and the buffer amplifier 23 each have an amplification factor of about 1, the subtraction amplifier 24 has an amplifier factor of about 4, and the buffer amplifier 26 and the buffer amplifier 28 each have an amplification factor of about 2. Before the amplified optical signal VBITS and the amplified initial voltage VBITR are largely amplified, the effect of the capacitor on the optical signal common output line 10 is equivalent to the effect of the capacitor on the initial voltage common output line 11.

Next, a description is given of operations of the post-stage of the photoelectric conversion device.

In this case, each of the photoelectric conversion units 30 outputs the amplified optical signal VBITS and the amplified initial voltage VBITR in chronological order.

In the first half period, the amplified optical signal VBITS from the predetermined photoelectric conversion unit 30 is inputted to the subtraction amplifier 24 through the buffer amplifier 22, and the amplified initial voltage VBITR from the predetermined photoelectric conversion unit 30 is also inputted to the subtraction amplifier 24 through the buffer amplifier 23. The subtraction amplifier 24 subtracts the amplified initial voltage VBITR from the amplified optical signal VBITS, thereby removing the noise voltage Voff of the amplified optical signal VBITS. An output signal of the subtraction amplifier 24 in the first half period becomes a signal which is obtained such that the amplified initial voltage VBITR is subtracted from the amplified optical signal VBITS and a resultant is multiplied by gain to be added with a reference voltage VREF.

Further, in the second half period, the voltage Vclamp1 is inputted to the subtraction amplifier 24 through the buffer amplifier 22 and the buffer amplifier 23. Accordingly, two input terminals of the subtraction amplifier 24 have no voltage difference, with the result that the output signal of the subtraction amplifier 24 in the second half period becomes the reference voltage VREF.

In this case, in the first half period and the second half period, an offset of each of the buffer amplifier 22, the buffer amplifier 23, and the subtraction amplifier 24 is superimposed on the output signal of the subtraction amplifier 24. The output signal of the subtraction amplifier 24 is inputted to the clamp circuit 25.

In the second half period, based on a clamp pulse ØCLAMP to the clamp circuit 25, a terminal (not shown) applied with the reference voltage VREF is connected to the output terminal of the clamp circuit 25. Accordingly, an output signal of the clamp circuit 25 in the second half period is clamped to the reference voltage VREF.

In the first half period, based on the clamp pulse ØCLAMP, the terminal (not shown) applied with the reference voltage VREF is not connected to the output terminal of the clamp circuit 25. Accordingly, a capacitor is provided between the input terminal of the clamp circuit 25 and the output terminal thereof, and the output signal of the clamp circuit 25 in the first half period becomes a signal obtained such that the output signal of the clamp circuit 25, which is clamped to the reference voltage VREF at the output terminal, in the previous period in the second half period, is subtracted from the output signal of the subtraction amplifier 24 at the input terminal in the first half period, and a resultant is added with the reference voltage VREF. As a result, the output signal of the clamp circuit 25 in the first half period becomes a signal obtained such that the amplified initial voltage VBITR is subtracted from the amplified optical signal VBITS and a resultant is multiplied by gain to be added with the reference voltage VREF. Note that an offset of each of the buffer amplifier 22, the buffer amplifier 23, and the subtraction amplifier 24 is superimposed on the output signal of the clamp circuit 25 in the first half period.

The output signal of the clamp circuit 25 is inputted to the buffer amplifier 26. An output signal of the buffer amplifier 26 is inputted to the sample hold circuit 27.

In the first half period, the sample hold circuit 27 samples the output signal of the buffer amplifier 26, which corresponds to the output signal of the clamp circuit 25 in the first half period, based on a sample hold pulse ØSH to the sample hold circuit 27.

Further, in the second half period, the sample hold circuit 27 holds the sampled signal based on the sample hold pulse ØSH, and an output signal of the sample hold circuit 27 is maintained for a long period of time.

The output signal of the sample hold circuit 27 is inputted to the buffer amplifier 28. An output signal of the buffer amplifier 28 is inputted to the transmission gate 29. The transmission gate 29 outputs an output voltage VOUT according to the amount of the photoelectric charges corresponding to the incident light.

In the above-mentioned configuration, the capacitor group 20 having the capacitance value substantially equal to the differential capacitance value between the first parasitic capacitor 31 associated with the optical signal common output line 10 and the second parasitic capacitor 32 associated with the initial voltage common output line 11 is connected to the optical signal common output line 10 or to the initial voltage common output line 11. Accordingly, the parasitic capacitance associated with the optical signal common output line 10 is equal to the parasitic capacitance associated with the initial voltage common output line 11. Therefore, the effect of the parasitic capacitance on the optical signal is eliminated and the optical signal is corrected with high accuracy.

Further, the capacitor group 20 is connected to the optical signal common output line 10 or to the initial voltage common output line 11, and the capacitor group 20 is not controlled by the signal. In addition, a time for controlling the capacitor group 20 is unnecessary. Accordingly, a time for reading the optical signal and the initial voltage is not reduced. As a result, the photoelectric conversion device is more adaptable to high-speed operations.

Even in a case where the number of each of the photodiode 1 and the photoelectric conversion units 30 increases or decreases, under the conditions at that time, the parasitic capacitance associated with the optical signal common output line 10 and the parasitic capacitance associated with the initial voltage common output line 11 are equal to each other. As a result, irrespective of the number of each of the photodiode 1 and the photoelectric conversion units 30, the effect of the parasitic capacitance on the optical signal is eliminated, and the optical signal is corrected with high accuracy.

Next, a description is given of the capacitor group 20. FIG. 4 is a diagram showing a first capacitor group.

As shown in FIG. 4, the capacitor group 20 includes a plurality of capacitors 20a and a plurality of metal wirings 20b. A plurality of capacitors 20a having the same capacitance value may be provided, or a plurality of capacitors 20a having different capacitance values may be provided. In each of the capacitors, the capacitors 20a are each connected to the optical signal common output line 10 or to the initial voltage common output line 11 via the corresponding metal wiring 20b.

In the above-mentioned configuration, when a mask used for producing a semiconductor device is changed and the metal wiring 20b is changed, the number of capacitors 20c to be connected to the optical signal common output line 10 or to the initial voltage common output line 11 is changed, the capacitance value of the capacitor group 20 is trimmed. Accordingly, the capacitance value substantially equal to the differential capacitance value between the first parasitic capacitor 31 and the second parasitic capacitor 32 is easily realized.

Next, a description is given of the capacitor group 20 different from that described in the above. FIG. 5 is a diagram showing a second capacitor group.

As shown in FIG. 5, the capacitor group 20 includes a plurality of capacitors 20c and a plurality of switches 20d. A plurality of capacitors 20c having the same capacitance value may be provided, or a plurality of capacitors 20c having different capacitance values may be provided. In each of the capacitors, the capacitors 20c are each connected to the optical signal common output line 10 or to the initial voltage common output line 11 through the corresponding switch 20d.

In the above-mentioned configuration, when the switches 20d are controlled to be turned on and off, the number of the capacitors 20a to be connected to the optical signal common output line 10 or to the initial voltage common output line 11 is changed, whereby the capacitance value of the capacitor group 20 is trimmed. Accordingly, the capacitance value substantially equal to the differential capacitance value between the first parasitic capacitor 31 and the second parasitic capacitor 32 is easily realized.

Note that the voltage Vclamp1 is generally a power supply voltage of each of the buffer amplifier 22 and the buffer amplifier 23.

In FIG. 2, the capacitor group 20 is connected to the initial voltage common output line 11, but may be connected to the optical signal common output line 10. In this case, the capacitor group 20 is connected to one of the optical signal common output line 10 and the initial voltage common output line 11 with a smaller parasitic capacitance.

In FIG. 4, all the capacitors 20a are connected to the optical signal common output line 10 or to the initial voltage common output line 11. Alternatively, a part of the capacitors 20a may be connected thereto. In this case, the capacitors 20a are connected thereto so that the capacitance value of the capacitor group 20 becomes the capacitance value substantially equal to the differential capacitance value between the first parasitic capacitor 31 and the second parasitic capacitor 32.

In FIG. 1, the photodiode is used, but a phototransistor may be used.

What is claimed is:

1. A photoelectric conversion device for outputting an output voltage according to incident light, comprising:
a plurality of photoelectric conversion units each including:
optical signal output means which outputs an optical signal according to the incident light;
reset means which is connected to an output terminal of the optical signal output means and which resets a voltage at the output terminal of the optical signal output means to a predetermined initial voltage;
amplification means which is connected to the output terminal of the optical signal output means and which amplifies the optical signal to output the amplified optical signal and amplifies the initial voltage to output the amplified initial voltage;
optical signal holding means which is connected to an output terminal of the amplification means and which holds the amplified optical signal; and
initial voltage holding means which is connected to the output terminal of the amplification means and which holds the amplified initial voltage;
an optical signal common output line commonly connected to all the plurality of photoelectric conversion units, for outputting the amplified optical signal from each of the plurality of photoelectric conversion units in chronological order, and having a first parasitic capacitance;
an initial voltage common output line commonly connected to all the plurality of photoelectric conversion units, for outputting the amplified initial voltage from each of the plurality of photoelectric conversion units in chronological order, and having a second parasitic capacitance;
an adjustment capacitor commonly connected to one of the optical signal common output line and the initial voltage common output line, which has a capacitance value substantially equal to a differential capacitance value between the first parasitic capacitance and the second parasitic capacitance; and
a subtraction amplifier for subtracting the amplified initial voltage from the amplified optical signal.

2. A photoelectric conversion device according to claim 1, wherein:
the adjustment capacitor includes a plurality of capacitors; and
the plurality of capacitors are each connected to one of the optical signal common output line and the initial voltage common output line via a metal wiring.

3. A photoelectric conversion device according to claim 1, wherein:
the adjustment capacitor includes a plurality of capacitors; and
the plurality of capacitors are each connected to one of the optical signal common output line and the initial voltage common output line via a switch circuit.
